(19) United States
(12) Patent Application Publication
(10) Pub. No.: US 2025/0253839 A1
(43) Pub. Date: Aug. 7, 2025

(54) LOAD SWITCHING DEVICE

(71) Applicant: STMicroelectronics International N.V., Geneva (CH)

(72) Inventor: Ghafour BENABDELAZIZ, Tours (FR)

(21) Appl. No.: 19/035,149

(22) Filed: Jan. 23, 2025

(30) Foreign Application Priority Data
Feb. 7, 2024 (FR) FR2401204

(51) Int. Cl. H03K 17/081

(52) U.S. Cl. CPC H03K 17/08108; H03K 2217/0009

(57) ABSTRACT

The present description concerns a device for switching a load, comprising two power thyristors coupled head-to-tail to each other, and a control thyristor having its anode coupled to the gate of a first one of the two power thyristors and having its cathode coupled to the anode of the first one of the two power thyristors.

### CROSS REFERENCE TO RELATED APPLICATIONS

This application is a translation of and claims the priority benefit of French patent application number 2401204, filed on Feb. 7, 2024, entitled “Dispositif de commutation de charge” which is hereby incorporated by reference to the maximum extent allowable by law.

### TECHNICAL FIELD

The present disclosure generally concerns the field of the switching of a load coupled to an electrical network.

### BACKGROUND

To control the switching of a load in an electric circuit coupled to an electrical network supplying, for example, an AC electric voltage, it is possible to use a power triac electrically coupled in series with the load within the electric circuit. However, problems of untimely starting of the triac may occur when the control is no longer applied to the gate of the triac, these problems being linked to the maximum variation of the off-state voltage of the triac (corresponding to the dV/dt problem at the switching of the triac) and to the maximum variation of the intensity of the direct current flowing through the triac (corresponding to the di/dt problem at the switching of the triac), particularly when the load having its switching controlled is inductive. These restarting problems are due to an excessive amount of electric charges accumulated in the triac, and which have to be extracted when it is turned off.

To avoid these restarting problems, it is possible to use, instead of the triac, two thyristors assembled head-to-tail, that is, coupled to each other and such that the cathode of one of them is connected to the anode of the other. Indeed, conversely to the triac, given that the thyristors used in this configuration are two separate components, the charges accumulated by one of the two thyristors are not seen by the other when they are blocked. Moreover, when the current flowing through one of the thyristors is cancelled to change polarity, this thyristor cannot be restarted, as it is then reverse-biased and the current will flow through the other thyristor. Another advantage provided by the use of two thyristors as compared with a triac is the lower level of current required for their control. However, this last advantage is counterbalanced by the fact that two distinct control signals are required to control these two thyristors. Indeed, the reference of each control signal, connected to the thyristor cathode, is not identical, which makes it difficult to obtain these two signals.

A solution enabling to have two control signals with two different references comprises forming a galvanic isolation between the gates of the two thyristors. This galvanic isolation is for example formed by using a pulse transformer provided with a primary having a single control signal applied thereto, and with two separate secondaries having the control signals applied to the gates of the two thyristors obtained thereon. Such a transformer however has the disadvantage of being bulky and expensive, due to the two necessary secondaries. Further, this solution requires rectifying diodes coupled to the thyristor gates. Further, this solution is a source of electromagnetic interference, is difficult to integrate, and offers a low control accuracy for the zero-voltage switching (ZVS) of the thyristors.

Another solution to form this galvanic isolation is to use an opto-triac comprising a triac, having each of its anodes coupled to one of the gates of the two thyristors, and an opto-coupler. In this other solution, the current originating from the network is used to form the thyristor control signals, limited by the load and the anode resistance of the opto-triac, which assumes the presence of a minimum grid voltage to start the thyristors. Such an opto-triac also has the disadvantage of requiring a buffer and rectifying diodes coupled to the thyristor gates. Further, this solution is difficult to integrate and offers a low control accuracy for the zero-voltage switching of the thyristors.

### BRIEF SUMMARY

There exists a need to provide a solution enabling to answer the problems encountered with existing solutions.

An embodiment overcomes all or part of the disadvantages of known solutions and provides a device for switching a load, comprising two power thyristors coupled head-to-tail to each other, and a control thyristor having its anode coupled to the gate of a first one of the two power thyristors and having its cathode coupled to the anode of the first one of the two power thyristors.

According to a particular embodiment, the anode of the first one of the two power thyristors is coupled to an electric reference potential.

According to a particular embodiment, the gate of a second one of the two power thyristors is coupled to a first control input of the device for switching the load, and the gate of the control thyristor is coupled to a second control input of the device for switching the load, separate from the first control input.

According to a particular embodiment, the gate of the control thyristor and the gate of a second one of the two power thyristors are coupled to a same control input of the device for switching the load.

According to a particular embodiment, the device for switching a load further comprises a transformer comprising a primary coupled to the control input of the device for switching the load and a secondary coupled to the gates of the control thyristor and of the second one of the two power thyristors.

According to a particular embodiment, the device for switching a load further comprises a voltage clamping circuit coupled across the primary of the transformer.

According to a particular embodiment, the voltage clamping circuit comprises a diode and a Zener diode coupled to each other such that: the cathode of the diode is coupled to one of the terminals of the primary of the transformer; the anode of the diode is coupled to the anode of the Zener diode; and the cathode of the Zener diode is coupled to the other one of the terminals of the primary of the transformer.

According to a particular embodiment, the device for switching a load further comprises a transistor having one of the source or drain electrodes coupled to the primary of the transformer, wherein the other one of the source or drain electrodes of the transistor and one of the terminals of the primary of the transformer are configured to form input terminals for a power supply voltage, and wherein the gate of the transistor is coupled to the control input of the device for switching the load.

According to a particular embodiment, the gate of the control thyristor and the gate of the second one of the two power thyristors are each coupled to an electric resistor.

It is also disclosed an electric circuit comprising: two input terminals having an AC electric voltage intended to be applied thereto; an electric load comprising a first electrode coupled to one of the two input terminals of the electric circuit; and a device for switching a load according to a particular embodiment, coupled between a second electrode of the electric load and the other of the two input terminals of the electric circuit.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an electric circuit comprising a first example of a load switching device according to a specific embodiment;

FIG. 2 shows the voltages obtained in the electric circuit of FIG. 1 during its operation;

FIG. 3 shows reverse currents obtained for two different control thyristors, according to the value of the current applied to their gate;

FIG. 4 shows values of reverse current/gate current ratios obtained for two different control thyristors;

FIG. 5 and FIG. 6 show voltage and current signals obtained in the electric circuit of FIG. 1 when the switched electric load is resistive;

FIG. 7 and FIG. 8 show voltage and current signals obtained in the electrical circuit of FIG. 1 when the switched electric load is inductive;

FIG. 9 shows an electric circuit comprising a second example of a load switching device according to a specific embodiment; and

FIG. 10 shows an electric circuit comprising a third example of a load switching device in a specific embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, different elements (thyristor, control circuit, transformer, etc.) of the electric circuit and of the load switching device are not detailed. Those skilled in the art will be capable of forming these elements in detailed fashion based on the description given herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, the term “coupled” is used herein to designate an electric coupling between a plurality of electric and/or electronic elements (components, circuits, etc.).

Unless specified otherwise, the expressions “about”, “approximately”, “substantially”, and “in the order of” signify plus or minus 10%, preferably of plus or minus 5%.

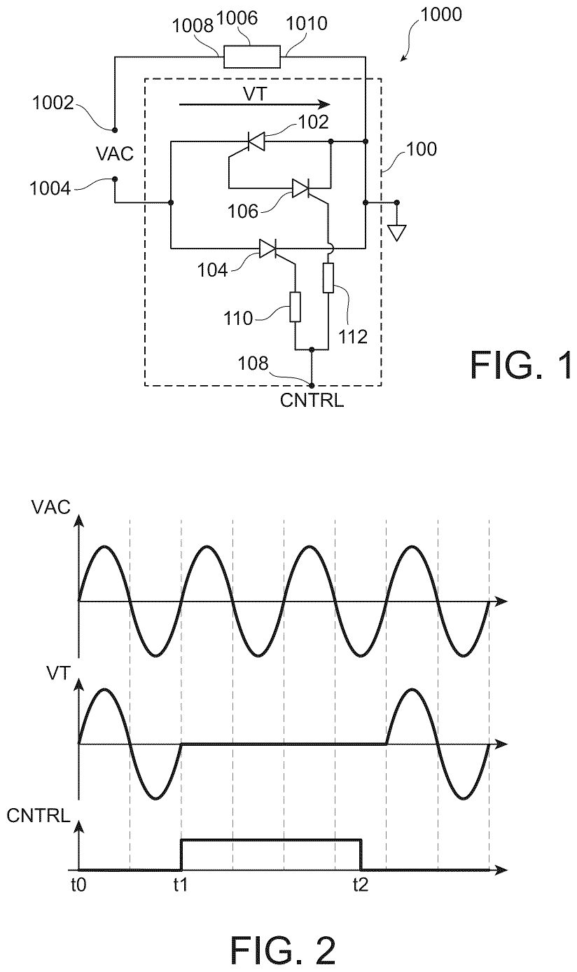

An electric circuit 1000 comprising a first example of a load switching device 100 according to a specific embodiment is described hereafter in relation with FIG. 1.

Circuit 1000 comprises two input terminals 1002, 1004 having an AC electric voltage, called VAC in FIG. 1, intended to be applied thereto, this AC electric voltage corresponding, for example, to a home network voltage such as a single-phase voltage.

Circuit 1000 also comprises an electric load 1006 comprising a first electrode 1008 coupled to one of the two input terminals of circuit 1000 (to terminal 1002 in the example of FIG. 1). Load 1006 also comprises a second electrode 1010 intended to be intermittently coupled to the other one of the two input terminals (to terminal 1004 in the example of FIG. 1) of circuit 1000. To obtain this intermittent coupling, circuit 1000 comprises a load switching device 100 coupled between the second electrode 1010 of electric load 1006 and the other input terminal 1004 of circuit 1000.

Device 100 comprises two power thyristors 102, 104 coupled head-to-tail to each other. In the example of FIG. 1, the first power thyristor 102 has its anode coupled to a reference electric potential, for example, the ground, and to the second electrode 1010 of load 1006. In the example of FIG. 1, the cathode of the first power thyristor 102 is coupled to the input terminal 1004 of circuit 1000. Further, in the example of FIG. 1, the second power thyristor 104 has its anode coupled to the input terminal 1004 of circuit 1000 (and thus also to the cathode of the first power thyristor 102) and its cathode coupled to the electric reference potential (and thus also to the anode of the first power thyristor 102 and to the second electrode 1010 of load 1006).

Device 100 further comprises a control thyristor 106 having its anode coupled to the gate of the first power thyristor 102 and having its cathode coupled to the anode of the first power thyristor 102.

In the first example of device 100 shown in FIG. 1, the gate of control thyristor 106 and the gate of the second power thyristor 104 are coupled to a same control input 108 of device 100.

Further, in the first example of device 100 shown in FIG. 1, the gate of control thyristor 106 and the gate of the second power thyristor 104 are each coupled to a separate electric resistor 110, 112 for each of the gates.

FIG. 2 shows curves of voltage obtained in the circuit 1000 of FIG. 1 during its operation, with an electric load 1006 corresponding to a resistive load.

Voltage VAC corresponds to the AC voltage applied to the input terminals 1002, 1004 of circuit 1000. Signal CNTRL corresponds to the control signal applied to the control input 108 of device 100. Voltage VT corresponds to the voltage obtained across the first and second power thyristors 102, 104.

In FIG. 2, between times to and t1, control signal CNTRL is zero and power thyristors 102, 104 are off. The obtained voltage VT thus corresponds to an AC voltage in phase with voltage VAC.

At time t1, the value of control signal CNTRL becomes positive and generates the flowing of a starting current through the gates of the second power thyristor 104 and of control thyristor 106. In the example of FIG. 1, time t1 also corresponds to the zero crossing, from a negative value to a positive value, of voltage VT. When voltage VAC is positive, a reverse current flowing through control thyristor 106 is sent to the gate of first power thyristor 102, which causes the starting and the setting to the on state of first power thyristor 102. When voltage VAC then becomes negative, the second power thyristor 104 is started and switches to the on state.

Between times t1 and t2, control signal CNTRL remains at a positive value and power thyristors 102, 104 are on. Voltage VT is thus substantially zero, and each of the power thyristors 102, 104 conducts the current flowing through load 1006 and device 100, one conducting the current when its value is positive (the first power thyristor 102 in the example of FIG. 1) and the other conducting the current when its value is negative (the second power thyristor 104 in the example of FIG. 1).

From time t2, control signal CNTRL returns to zero. As soon as voltage VT crosses zero, thyristors 102, 104 switch back to the off state, and voltage VT becomes an AC voltage in phase with voltage VAC again.

Thus, control thyristor 106 forms a driving component, that is, a driver, controlling in reverse the first power thyristor 102, due to the fact that it forms a current source controlling the gate current of the first power thyristor 102. The value of the reverse current of the control thyristor 106 depends on the value of the current flowing through the gate of the control thyristor 106.

As an example, power thyristors 102, 104 may be sized to be able to conduct power currents of several amperes or several tens or hundreds of amperes, while control thyristor 106 may be sized to conduct a control current with a maximum value lower than 1 A, for example lower than or equal to 200 mA.

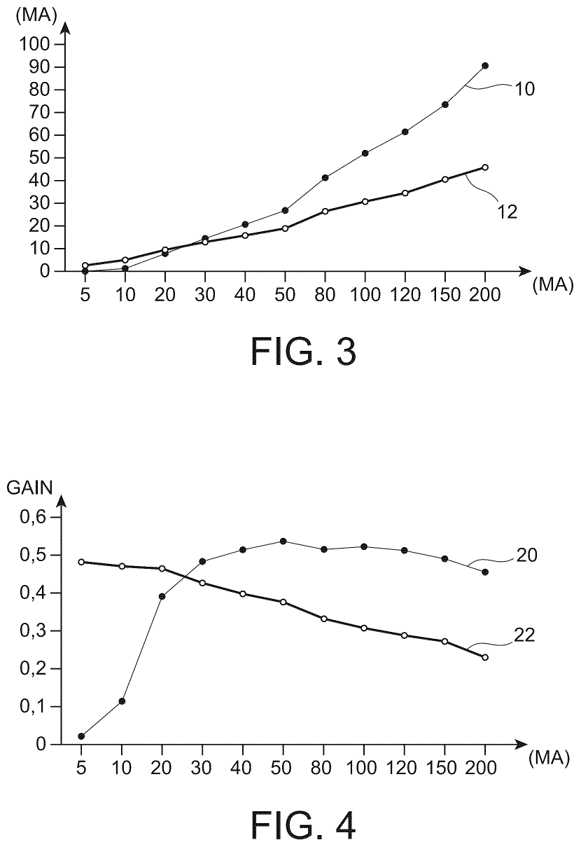

The curves 10 and 12 shown in FIG. 3 show reverse current values obtained for two different control thyristors, according to the value of the current applied to their gate. The curves 20 and 22 shown in FIG. 4, show values of reverse current/gate current ratios obtained for these control thyristors.

In circuit 1000, the value of the power current intended to flow through load 1006 and power thyristors 102, 104 depends on the impedance value of electric load 1006 and on voltage VAC. Power thyristors 102, 104 may thus be sized and selected according to the value of this power current. Control thyristor 106 may then be selected and sized according to the control current required to control the first power thyristor 102, that is, such that control thyristor 106 can generate a reverse current sufficient to be used as the current for controlling the first power thyristor 102.

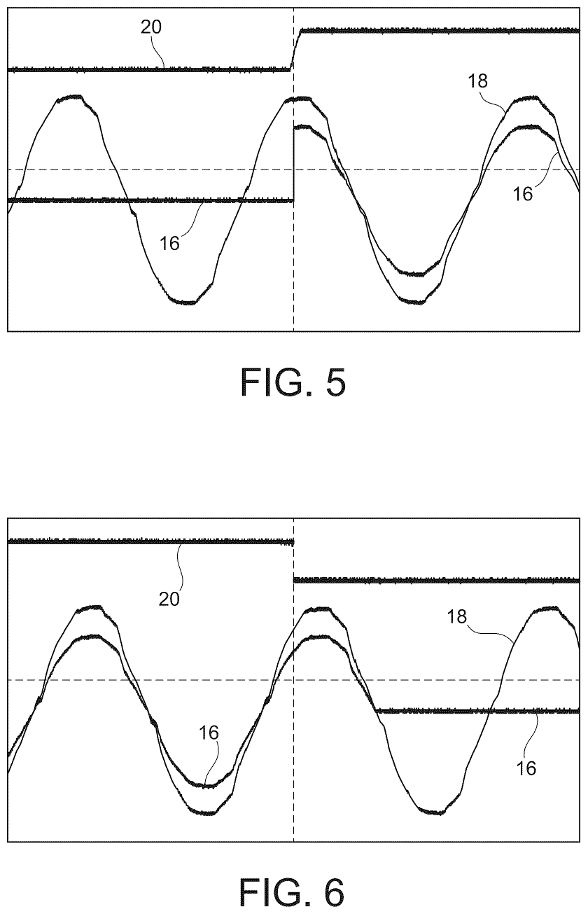

In FIGS. 5 and 6, reference numeral 16 designates the value of the current flowing through a resistive electric load 1006 and device 100, reference numeral 18 designates voltage VAC, and reference numeral 20 designates control signal CNTRL. As shown in FIG. 5, the current in electric load 1006 is zero as long as the value of control signal CNTRL is zero. When the value of control signal CNTRL becomes positive, a non-zero current flows through electric load 1006 and device 100, in phase with voltage VAC. Then, as shown in FIG. 6, when the value of control signal CNTRL returns to zero, the value of the current flowing through electric load 1006 and device 100 returns to zero as soon as voltage VAC crosses a zero value.

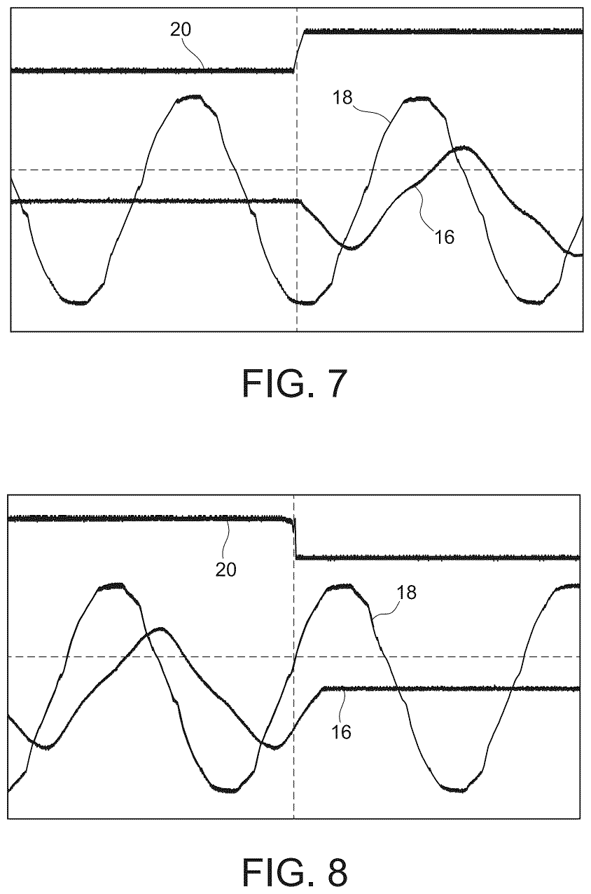

The signals 16, 18, and 20 shown in FIGS. 7 and 8 are similar to those previously described in relation with FIGS. 5 and 6, but in the case where electric load 1006 is inductive. In this configuration, when a non-zero current flows through electric load 1006 and device 100, this current is phase-shifted with respect to voltage VAC.

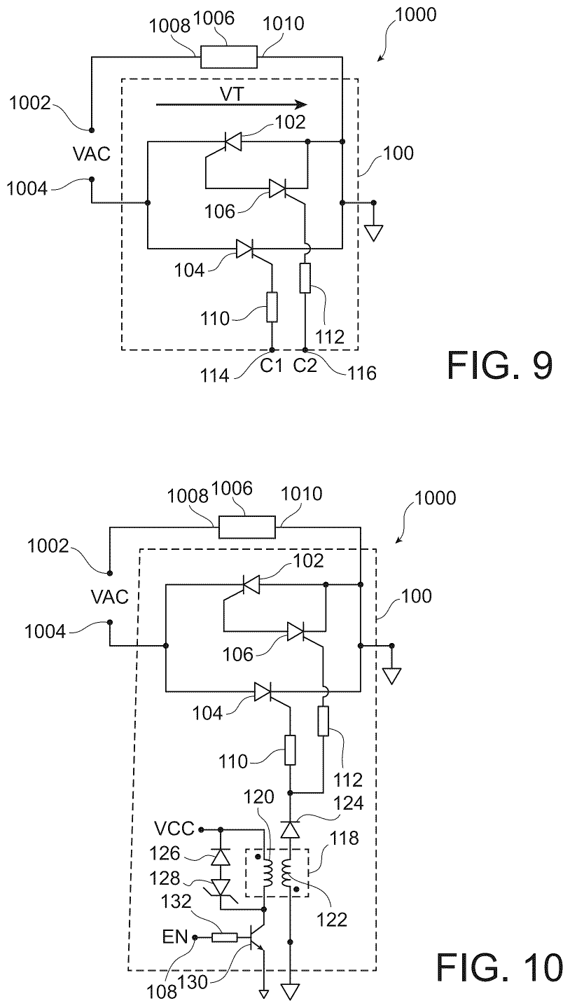

A second example of an electric circuit 1000 comprising a load switching device 100 according to a specific embodiment is described hereafter in relation with FIG. 9.

The electric circuit 1000 according to this second example of embodiment comprises the same elements as those of the previously described first example. However, conversely to the first example where the gates of control thyristor 106 and of the second power thyristor 104 are coupled to the same control input 108 of device 100, the gate of the second power thyristor 104 is coupled to a first control input 114 of device 100, and the gate of control thyristor 106 is coupled to a second control input 116 of device 100, distinct from the first control input 114. Distinct control signals, for example called C1 and C2 in FIG. 9, are applied to these control inputs 114, 116. The operation of device 100 in this second example is similar to that of the device 100 according to the first previously described example, signals C1 and C2 being for example similar to the control signal CNTRL previously described in relation with the first example.

A third example of an electric circuit 1000 comprising a load switching device 100 according to a specific embodiment is described hereafter in relation with FIG. 10.

The electric circuit 1000 according to this third example comprises the same elements as those of the first example described above. However, in this third example, device 100 also comprises a galvanic isolation between the control portion of device 100 and the power portion of device 100. According to an example corresponding to that shown in FIG. 10, this galvanic isolation may be obtained by a transformer 118 comprising a primary 120 coupled to the control input 108 of device 100 and a secondary 122 coupled to the gates of control thyristor 106 and of the second power thyristor 104.

In the example of FIG. 10, device 100 also comprises a diode 124 coupled between electric resistors 110, 112 and a first terminal of the secondary 122 of transformer 118. A second terminal of the secondary 122 of transformer 118 is coupled to the electric reference potential of circuit 1000.

In the example of FIG. 10, device 100 further includes a voltage clamping circuit coupled across the primary 120 of transformer 118. According to an example of embodiment, this voltage clamping circuit comprises a diode 126 and a Zener diode 128 coupled to each other, such that: the cathode of diode 126 is coupled to one of the terminals of the primary 120 of transformer 118 and to an electric power supply potential (VCC) of device 100; the anode of diode 126 is coupled to the anode of Zener diode 128; and the cathode of Zener diode 128 is coupled to the other one of the terminals of the primary 120 of transformer 118.

As a variant, the voltage clamping circuit could be designed differently from the circuit of FIG. 10.

In the described example of embodiment, device 100 further comprises a transistor 130 having one of its source or drain electrodes coupled to one of the terminals of the primary 120 of transformer 118. The other source or drain electrode of transistor 130 is coupled to the electric reference potential of device 100. Further, the gate of transistor 130 is coupled to the control input 108 of device 100 via another electric resistor 132.

As a variant, a voltage clamping circuit, similar to or different from that previously described in relation with the device of FIG. 10, could be coupled to each of the control inputs 114, 116 of the device 100 previously described in relation with FIG. 9.

Among the advantages provided by device 100, for all the examples of embodiment, it is possible to mention those below:
no problem of untimely restarting if the control is no longer applied when the power current is cancelled, as is the case when a triac is used for the switching of the load in the electric circuit;
possibility of having a single control signal to perform the load switching;
absence of the disadvantages of a pulse transformer or of an opto-triac;
decreased power consumption due to the use of the control thyristor;
better accuracy of the control for the zero-voltage switching of thyristors than with a pulse transformer or an opto-triac;
better integration of the device.

Device 100 may be used in an electric circuit 1000 of a device in the industrial field, in a household appliance, in an electric vehicle, etc.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

That which is claimed:

1. A device for switching a load, comprising:
two power thyristors coupled head-to-tail to each other; and
a control thyristor having an anode coupled to a gate of a first one of the two power thyristors and having a cathode coupled to an anode of the first one of the two power thyristors;
wherein (i) a gate of a second one of the two power thyristors is coupled to a first control input of the device for switching the load, and a gate of the control thyristor is coupled to a second control input of the device for switching the load, separate from the first control input or (ii) a gate of the control thyristor and a gate of a second one of the two power thyristors are coupled to a same control input of the device for switching the load.

2. The device for switching a load according to claim 1, wherein the anode of the first one of the two power thyristors is coupled to an electric reference potential.

3. The device for switching a load according to claim 1, further comprising a transformer comprising a primary coupled to the control input of the device for switching the load and a secondary coupled to the gates of the control thyristor and of the second one of the two power thyristors.

4. The device for switching a load according to claim 3, further comprising a voltage clamping circuit coupled across the primary of the transformer.

5. The device for switching a load according to claim 4, wherein the voltage clamping circuit comprises a diode and a Zener diode coupled to each other such that the cathode of the diode is coupled to one of two or more terminals of the primary of the transformer, the anode of the diode is coupled to the anode of the Zener diode, and the cathode of the Zener diode is coupled to an other one of the two or more terminals of the primary of the transformer.

6. The device for switching a load according to claim 3, further comprising a transistor having one of a source electrode or a drain electrode coupled to the primary of the transformer;
wherein an other one of the source electrode or the drain electrode of the transistor and one of two or more terminals of the primary of the transformer are configured to form input terminals for a power supply voltage; and
wherein a gate of the transistor is coupled to the control input of the device for switching the load.

7. The device for switching a load according to claim 1, wherein a gate of the control thyristor and a gate of the second one of the two power thyristors are each coupled to an electric resistor.

8. An electric circuit comprising:
two input terminals having an AC electric voltage intended to be applied thereto;
an electric load comprising a first electrode coupled to one of the two input terminals of the electric circuit; and
a device for switching a load coupled between a second electrode of the electric load and the other of the two input terminals of the electric circuit, the device for switching a load comprising:
two power thyristors coupled head-to-tail to each other; and
a control thyristor having an anode coupled to a gate of a first one of the two power thyristors and having a cathode coupled to an anode of the first one of the two power thyristors;
wherein (i) a gate of a second one of the two power thyristors is coupled to a first control input of the device for switching the load, and a gate of the control thyristor is coupled to a second control input of the device for switching the load, separate from the first control input or (ii) a gate of the control thyristor and a gate of a second one of the two power thyristors are coupled to a same control input of the device for switching the load.

9. The electric circuit according to claim 8, wherein the anode of the first one of the two power thyristors is coupled to an electric reference potential.

10. The electric circuit according to claim 8, wherein the device for switching a load further comprises a transformer comprising a primary coupled to the control input of the device for switching the load and a secondary coupled to the gates of the control thyristor and of the second one of the two power thyristors.

11. The electric circuit according to claim 10, wherein the device for switching a load further comprises a voltage clamping circuit coupled across the primary of the transformer.

12. The electric circuit according to claim 11, wherein the voltage clamping circuit comprises a diode and a Zener diode coupled to each other such that the cathode of the diode is coupled to one of two or more terminals of the primary of the transformer, the anode of the diode is coupled to the anode of the Zener diode, and the cathode of the Zener diode is coupled to an other one of the two or more terminals of the primary of the transformer.

13. The electric circuit according to claim 10, wherein the device for switching a load further comprises a transistor having one of a source electrode or a drain electrode coupled to the primary of the transformer;
wherein an other one of the source electrode or the drain electrode of the transistor and one of two or more terminals of the primary of the transformer are configured to form input terminals for a power supply voltage; and
wherein a gate of the transistor is coupled to the control input of the device for switching the load.

14. The electric circuit according to claim 8, wherein a gate of the control thyristor and a gate of the second one of the two power thyristors are each coupled to an electric resistor.
